(19) United States
(12) Patent Application Publication
(10) Pub. No.: US 2021/0130958 A1
(43) Pub. Date: May 6, 2021

(54) HEATING APPARATUS AND CHEMICAL VAPOR DEPOSITION SYSTEM

(71) Applicant: PlayNitride Display Co., Ltd., MiaoLi County (TW)

(72) Inventors: Jyun-De Wu, MiaoLi County (TW); Yen-Lin Lai, MiaoLi County (TW); Chi-Heng Chen, MiaoLi County (TW)

(73) Assignee: PlayNitride Display Co., Ltd., MiaoLi County (TW)

(21) Appl. No.: 16/878,582

(22) Filed: May 19, 2020

(30) Foreign Application Priority Data
Nov. 6, 2019 (TW) 108140232

(51) Int. Cl. C23C 16/46; C23C 16/458

(52) U.S. Cl. CPC C23C 16/46; C23C 16/4584

(57) ABSTRACT

A heating apparatus including a rotating stage, a plurality of wafer carriers, a plurality of first heaters, and at least one second heater is provided. The rotating stage includes a rotating axis. The plurality of wafer carriers is disposed on the rotating stage. The rotating stage drives the wafer carriers to rotate by taking the rotating axis as a center. The plurality of first heaters is disposed under a first heating region of the rotating stage. There is a first spacing between any two adjacent first heaters. The at least one second heater is disposed under a second heating region of the rotating stage. There is a spacing between the second heating region and the first heating region, and the spacing is not equal to the first spacing. A chemical vapor deposition (CVD) system using the heating apparatus is also provided.

### CROSS-REFERENCE TO RELATED APPLICATION

This application claims the priority benefit of Taiwan application serial no. 108140232, filed on Nov. 6, 2019. The entirety of the above-mentioned patent application is hereby incorporated by reference herein and made a part of this specification.

### BACKGROUND OF THE INVENTION

### Field of the Invention

The disclosure relates to a film deposition apparatus, and in particular, to a heating apparatus and a chemical vapor deposition (CVD) system.

### Description of Related Art

With continuous improvements in operating performance and reliability of light-emitting diode materials, the light-emitting diode materials are gradually applied to diversified fields, for example, lighting devices, displays, and backlight modules. To satisfy performance specifications under various different usage requirements, light-emitting diode elements of different structures or materials continuously challenge design and mass production capabilities of relevant manufacturers. For example, to meet a required display quality (for example, color rendering or brightness uniformity of a display surface) requirement, film thickness uniformity of an epitaxial layer of a micro light-emitting diode applied to a display needs to be better.

In a process of forming an epitaxial film of a micro light-emitting diode element, a CVD technology is one of the commonly used technical means. However, as the size of the epitaxial substrate increases and the size of the light-emitting diode element decreases, the traditional CVD device can no longer satisfy the temperature uniformity requirement of the epitaxial substrate during film formation.

### SUMMARY OF THE INVENTION

The invention provides a heating apparatus, which may provide favorable temperature uniformity of an epitaxial substrate.

The invention provides a CVD system, which has favorable film uniformity.

The heating apparatus of the invention includes a rotating stage, a plurality of wafer carriers, a plurality of first heaters, and at least one second heater. The rotating stage includes a rotating axis. The plurality of wafer carriers is disposed on the rotating stage. The rotating stage drives the wafer carriers to rotate on the rotating axis. The plurality of first heaters is disposed under a first heating region of the rotating stage. There is a first spacing between any two adjacent first heaters. The first heaters each include a first width in a radial direction of the rotating stage. The at least one second heater is disposed under a second heating region of the rotating stage. The second heater includes a second width in the radial direction of the rotating stage, and the first width is equal to the second width. There is a spacing between the second heating region and the first heating region, and the spacing is not equal to the first spacing.

In an embodiment of the invention, the spacing of the heating apparatus between the second heating region and the first heating region is the smallest spacing between the second heater and one of the first heaters.

In an embodiment of the invention, the first heating region of the heating apparatus includes a radial width in the radial direction of the rotating stage. The wafer carrier includes a wafer carrier diameter, and a ratio of the radial width to the wafer carrier diameter is greater than 0.5 and less than 1.

In an embodiment of the invention, the second heating region of the heating apparatus includes a plurality of second heaters, there is a second spacing between any two adjacent second heaters, and the second spacing is not equal to the first spacing.

In an embodiment of the invention, a ratio of a vertical projection area of the plurality of first heaters of the heating apparatus on the rotating stage to a vertical projection area of the first heating region on the rotating stage is not equal to a ratio of a vertical projection area of the plurality of second heaters on the rotating stage to a vertical projection area of the second heating region on the rotating stage.

In an embodiment of the invention, the plurality of first heaters of the heating apparatus includes a first temperature, the second heater includes a second temperature, and the first temperature is not equal to the second temperature.

In an embodiment of the invention, a vertical projection of each wafer carrier of the heating apparatus on the rotating stage partially overlaps a vertical projection of the first heating region on the rotating stage, and a ratio of a vertical projection area of the first heating region on the wafer carrier to an area of the wafer carrier is greater than or equal to 0.4 and less than or equal to 0.9.

In an embodiment of the invention, the plurality of wafer carriers of the heating apparatus includes a symmetry center each, and the symmetry centers overlap a vertical projection of the first heating region on the wafer carriers.

The CVD system of the invention includes a chamber, a heating apparatus, a rotation driving mechanism, and an air inlet unit. The heating apparatus is disposed in the chamber. The heating apparatus includes a rotating stage, a plurality of wafer carriers, a plurality of first heaters, and at least one second heater. The rotating stage includes a rotating axis. The plurality of wafer carriers is disposed on the rotating stage. The rotating stage drives the wafer carriers to rotate on the rotating axis. The first heaters are disposed under a first heating region of the rotating stage. There is a first spacing between any two adjacent first heaters. The first heaters each include a first width in a radial direction of the rotating stage. The at least one second heater is disposed under a second heating region of the rotating stage. The second heater includes a second width in the radial direction of the rotating stage, and the first width is equal to the second width. There is a spacing between the second heating region and the first heating region, and the spacing is not equal to the first spacing. The rotation driving mechanism is connected to the rotating stage and drives the rotating stage to rotate. The air inlet unit is disposed in the chamber and located above the rotating stage.

In an embodiment of the invention, the spacing of the CVD system between the second heating region and the first heating region is the smallest spacing between the second heater and one of the first heaters.

In an embodiment of the invention, the first heating region of the CVD system includes a radial width in the radial direction of the rotating stage. The wafer carrier includes a wafer carrier diameter, and a ratio of the radial width to the wafer carrier diameter is greater than 0.5 and less than 1.

In an embodiment of the invention, the second heating region of the CVD system includes a plurality of second heaters, there is a second spacing between any two adjacent second heaters, and the second spacing is not equal to the first spacing.

In an embodiment of the invention, a ratio of a vertical projection area of the plurality of first heaters of the CVD system on the rotating stage to a vertical projection area of the first heating region on the rotating stage is not equal to a ratio of a vertical projection area of the plurality of second heaters on the rotating stage to a vertical projection area of the second heating region on the rotating stage.

In an embodiment of the invention, the plurality of first heaters of the CVD system includes a first temperature, the second heater includes a second temperature, and the first temperature is not equal to the second temperature.

In an embodiment of the invention, a vertical projection of each wafer carrier of the CVD system on the rotating stage partially overlaps a vertical projection of the first heating region on the rotating stage, and a ratio of a vertical projection area of the first heating region on the wafer carrier to an area of the wafer carrier is greater than or equal to 0.4 and less than or equal to 0.9.

In an embodiment of the invention, the plurality of wafer carriers of the CVD system includes a symmetry center each, and the symmetry centers overlap a vertical projection of the first heating region on the wafer carriers.

In an embodiment of the invention, there is a spacing between each of the plurality of wafer carriers of the CVD system and the rotating stage in an axial direction of the rotating axis.

In an embodiment of the invention, there is a first distance between a first wafer carrier of the plurality of wafer carriers of the CVD system and the rotating stage in the axial direction of the rotating axis, there is a second distance between a second wafer carrier of the plurality of wafer carriers and the rotating stage in the axial direction of the rotating axis, and the first distance is not equal to the second distance.

In an embodiment of the invention, the heating apparatus of the CVD system further includes a wafer carrier driving unit, disposed on the rotating stage, and configured to drive each of the plurality of wafer carriers to respectively spin on its spinning axis.

In an embodiment of the invention, the wafer carrier driving unit of the CVD system includes a plurality of gas pipelines disposed in the rotating stage, and the gas pipelines are located under the plurality of wafer carriers.

Based on the above, in the heating apparatus and the CVD system in an embodiment of the invention, the first spacing between two adjacent first heaters located in the first heating region is not equal to the spacing between the first heating region and the second heating region, so that temperature uniformity of an epitaxial substrate can be effectively improved, a film developed on the epitaxial substrate may have favorable thickness uniformity, and uniformity of light emission of a subsequently formed micro light-emitting diode chip is also improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic partial exploded view of a heating apparatus according to a first embodiment of the invention.

FIG. 2 is a schematic cross-sectional view of a CVD system according to an embodiment of the invention.

FIG. 3 is a schematic cross-sectional view of a heating apparatus according to a second embodiment of the invention.

FIG. 4 is a schematic cross-sectional view of a heating apparatus according to a third embodiment of the invention.

FIG. 5 is a schematic top view of the heating apparatus in FIG. 4.

FIG. 6 is a schematic partial exploded view of a heating apparatus according to a fourth embodiment of the invention.

FIG. 7 is a schematic cross-sectional view of a CVD system according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

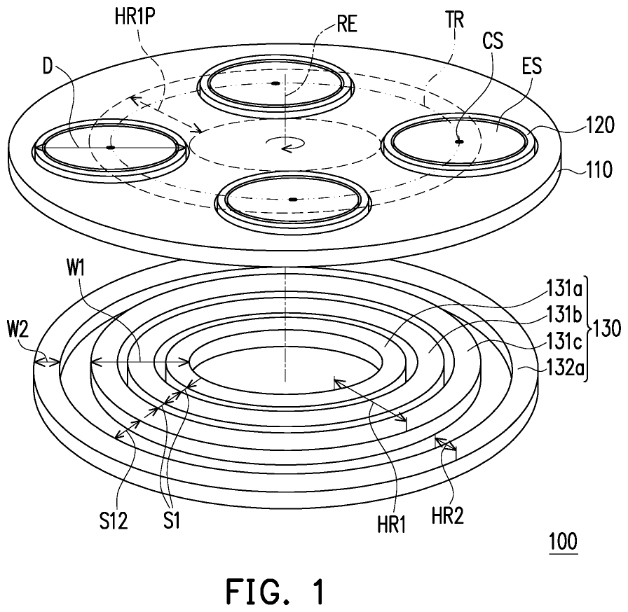

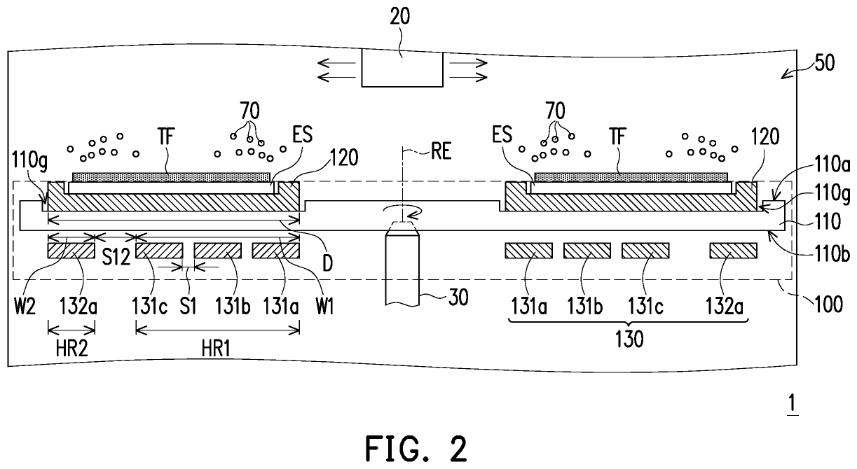

FIG. 1 is a schematic partial exploded view of a heating apparatus according to a first embodiment of the invention. FIG. 2 is a schematic cross-sectional view of a CVD system according to an embodiment of the invention. Referring to FIG. 1 and FIG. 2, the CVD system 1 includes a chamber 50, a heating apparatus 100, an air inlet unit 20, and a rotation driving mechanism 30. The heating apparatus 100 includes a rotating stage 110, a plurality of wafer carriers 120, and a heater 130. The wafer carrier 120 is configured to position an epitaxial substrate ES on the rotating stage 110. The wafer carrier 120 and the heater 130 are respectively disposed on two opposite sides of the rotating stage 110. Specifically, the rotating stage 110 includes a first surface 110a and a second surface 110b that are opposite and a plurality of grooves 110g provided on the first surface 110a. These wafer carriers 120 are respectively disposed in these grooves 110g, and protruding from the first surface 110a of the rotating stage 110. The second surface 110b of the rotating stage 110 is facing the heater 130.

In the present embodiment, for example, there are four wafer carriers 120, but this does not indicate that the invention is limited by the content disclosed in the figure. In other embodiments, the number of the wafer carriers 120 may be adjusted according to an actual process requirement (for example, the size of the epitaxial substrate or the rotating stage). The heating apparatus 100 is disposed in the chamber 50. The rotation driving mechanism 30 is linked to the rotating stage 110 to drive the rotating stage 110 to rotate. The air inlet unit 20 is connected to the chamber 50 and located above the rotating stage 110. In the present embodiment, the air flows into the chamber 50 from two sides of the air inlet unit 20, but is not limited thereto. In other embodiments, an air inlet opening may also be disposed below the air inlet unit 20. During film formation, the heating apparatus 100 may maintain a surface temperature of the epitaxial substrate ES at a predetermined value, the rotation driving mechanism 30 is used to drive the rotating stage 110 to maintain a rotation speed. Meanwhile, a process gas 70 (for example, a vaporized precursor or other reaction gases) is delivered to the chamber 50 through the air inlet unit 20, and a required epitaxial film TF is formed on the epitaxial substrate ES through chemical reaction of these process gases 70. In the present embodiment, the epitaxial substrate ES is, for example, a silicon wafer, a sapphire substrate, a silicon carbide (SiC) substrate, or other suitable substrates, and the epitaxial film TF is, for example, a gallium nitride (GaN) film, but is not limited thereto.

Further, the rotating stage 110 also includes a rotating axis RE, and each of these wafer carriers 120 is driven by the rotating stage 110 to rotate on the rotating axis RE. In the present embodiment, for example, there are four heaters 130, namely, a first heater 131a, a first heater 131b, a first heater 131c, and a second heater 132a, and the first heater 131a, the first heater 131b, the first heater 131c, and the second heater 132a are sequentially disposed away from a radial direction of the rotating stage 110, but the invention is not limited thereto. In other embodiments, alternatively, the second heater 132a may be located between the first heater and the rotating axis RE. From another point of view, the first heater 131a, the first heater 131b, and the first heater 131c may define a first heating region HR1, the second heater 132a may define a second heating region HR2, and in the radial direction of the rotating stage 110, the first heating region HR1 is optionally located between the second heating region HR2 and the rotating axis RE, but is not limited thereto.

It should be noted that, there is a first spacing 51 between any two adjacent first heaters (for example, the first heater 131a and the first heater 131b or the first heater 131b and the first heater 131c) located in the first heating region HR1 in the radial direction of the rotating stage 110. There is a spacing S12 between the first heating region HR1 and the second heating region HR2 in the radial direction of the rotating stage 110, and the spacing S12 is not equal to the first spacing 51. In the present embodiment, the spacing S12 is the smallest spacing between the second heater 132a and the first heater 131c that are adjacent. For example, the spacing S12 may be optionally greater than the first spacing 51, but is not limited thereto. In the present embodiment, vertical projections of these heaters 130 on the rotating stage 110 may surround the rotating axis RE. However, the invention is not limited thereto. According to other embodiments, the heater may include a plurality of separated segments, and these segments are respectively disposed in a plurality of sections overlapping rotation paths of these wafer carriers 120.

In addition, the wafer carrier 120 includes a symmetry center CS, and the rotating stage 110 rotates to drive the symmetry center CS to form a rotation track TR surrounding the rotating axis RE. It is specially noted that, in an axial direction of the rotating axis RE, the rotation track TR overlaps a vertical projection HR1P of the first heating region HR1 on the rotating stage 110. In other words, in a rotation process of the wafer carrier 120, the symmetry center CS of the wafer carrier 120 always overlaps the vertical projection HR1P of the first heating region HR1 on the wafer carrier 120. In the present embodiment, rotation paths of the plurality of wafer carriers 120 roughly overlap each other (that is, the rotation tracks TR of the symmetry centers CS of these wafer carriers 120 roughly overlap each other), but the invention is not limited thereto. In other embodiments, alternatively, the rotation tracks TR of the symmetry centers CS of these wafer carriers 120 may be staggered from each other.

The first heating region HR1 includes a radial width W1 in the radial direction of the rotating stage 110, and the wafer carrier 120 includes a wafer carrier diameter D in the radial direction of the rotating stage 110 (that is, the radial direction of the rotating stage 110 herein passes through the symmetry center CS of the wafer carrier 120). It is specially noted that, a ratio of the radial width W1 of the first heating region HR1 to the wafer carrier diameter D of the wafer carrier 120 may be greater than 0.5 and less than 1. Therefore, the first heater 131a, the first heater 131b, and the first heater 131c located in the first heating region HR1 may beat only a partial region of the wafer carrier 120, helping improve temperature uniformity of the epitaxial substrate ES, and enabling the epitaxial film TF developed on the epitaxial substrate ES to have favorable thickness uniformity. In some embodiments, a ratio of a vertical projection area of the first heating region HR1 on the wafer carrier 120 to an area of the wafer carrier 120 may be greater than or equal to 0.4 and less than or equal to 0.9, helping further improve the temperature uniformity of the epitaxial substrate ES.

Further, the second heating region HR2 also partially overlaps the wafer carrier 120 in the axial direction of the rotating axis RE, the second heating region HR2 includes a radial width W2 in the radial direction of the rotating stage 110, and the radial width W2 is not equal to the radial width W1 of the first heating region HR1. More specifically, the radial width W2 of the second heating region HR2 is less than the radial width W1 of the first heating region HR1. In the present embodiment, the first heater 131a, the first heater 131b, and the first heater 131c each have a first temperature, the second heater 132a has a second temperature, and the first temperature is not equal to the second temperature, so that the heater 130 can heat a plurality of regions of the wafer carrier 120, helping improve the temperature uniformity of the epitaxial substrate ES, and enabling the epitaxial film TF developed on the epitaxial substrate ES to have favorable thickness uniformity. It should be understood that, in the present embodiment, the epitaxial substrate ES may be heated through thermal radiation and thermal conduction. More specifically, thermal energy provided by the heater 130 may be transmitted to the second surface 110b of the rotating stage 110 through thermal radiation, and then transmitted to the epitaxial substrate ES through thermal conduction of the rotating stage 110 and the wafer carrier 120, but the invention is not limited thereto.

The following is to list some other embodiments to describe the disclosure in detail, the same components are to be marked with the same symbols, and descriptions of the same technical content are omitted. For the omitted part, refer to the above embodiments, and the descriptions thereof are omitted below.

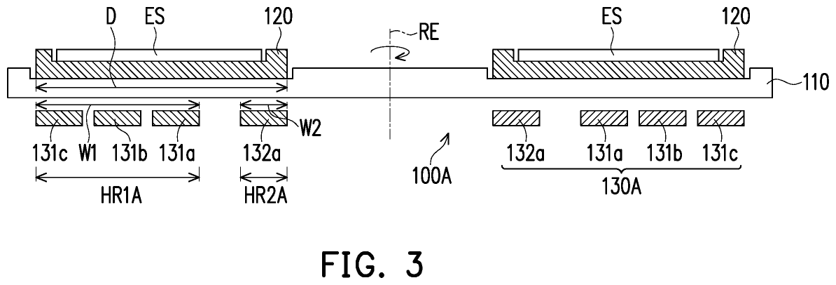

FIG. 3 is a schematic cross-sectional view of a heating apparatus according to a second embodiment of the invention. Referring to FIG. 3, a main difference between the heating apparatus 100A in the present embodiment and the heating apparatus 100 in FIG. 2 is that the heater is configured in different manners. Specifically, in the radial direction of the rotating stage 110, a second heating region HR2A is optionally disposed between a first heating region HR1A and the rotating axis RE. That is, the second heater 132a may be located between the first heater and the rotating axis RE. In the present embodiment, a configuration relationship between the first heating region HR1A and the wafer carrier 120 is similar to that of the heating apparatus 100 in the foregoing embodiment, and the descriptions thereof are omitted herein.

It is specially noted that, a ratio of a radial width W1 of the first heating region HR1A to the wafer carrier diameter D of the wafer carrier 120 is greater than 0.5 and less than 1. Therefore, the first heater 131a, the first heater 131b, and the first heater 131c may beat only a partial region of the wafer carrier 120, helping improve temperature uniformity of the epitaxial substrate ES, and enabling the epitaxial film TF developed on the epitaxial substrate ES to have favorable thickness uniformity. In addition, the second heating region HR2A has a radial width W2 in the radial direction of the rotating stage 110, and the radial width W2 is not equal to the radial width W1 of the first heating region HR1A. More specifically, the radial width W2 of the second heating region HR2A is less than the radial width W1 of the first heating region HR1A. In the present embodiment, the first heater 131a, the first heater 131b, and the first heater 131c each have a first temperature, the second heater 132a has a second temperature, and the first temperature is not equal to the second temperature, so that the heater 130A can heat a plurality of regions of the wafer carrier 120, helping improve the temperature uniformity of the epitaxial substrate ES, and enabling the epitaxial film TF developed on the epitaxial substrate ES to have favorable thickness uniformity.

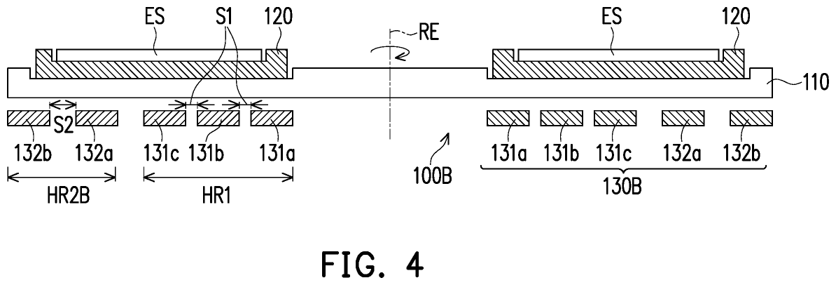

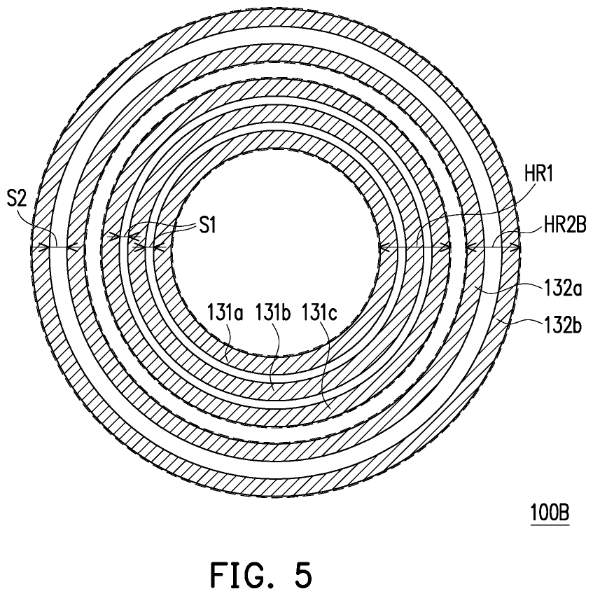

FIG. 4 is a schematic cross-sectional view of a heating apparatus according to a third embodiment of the invention. FIG. 5 is a schematic top view of the heating apparatus in FIG. 4. It is specially noted that, for clear presentation, FIG. 5 shows only the heater 130B and the heating regions in FIG. 4. Referring to FIG. 4 and FIG. 5, a main difference between the heating apparatus 100B in the present embodiment and the heating apparatus 100 in FIG. 2 is that the number of the second heaters is different. In the present embodiment, for example, the heating apparatus 100B includes two second heaters, namely, a second heater 132a and a second heater 132b. In the radial direction of the rotating stage 110, the second heater 132b is disposed on a side of the second heater 132a away from the rotating axis RE. In the present embodiment, a configuration relationship between the first heater 131a, the first heater 131b, the first heater 131c, the second heater 132a, and the wafer carrier 120 is similar to that of the heating apparatus 100, and descriptions thereof are omitted herein.

Further, there is a second spacing S2 between the second heater 132a and the second heater 132b located in the second heating region HR2B in the radial direction of the rotating stage 110, and the second spacing S2 is not equal to the first spacing S1 between any two adjacent first heaters. For example, the second spacing S2 is optionally greater than the first spacing S1, but is not limited thereto. It should be noted that, a ratio of a vertical projection area of the first heater 131a, the first heater 131b, and the first heater 131c on the rotating stage 110 to a vertical projection area of the first heating region HR1 on the rotating stage 110 is not equal to a ratio of a vertical projection area of the second heater 132a and the second heater 132b on the rotating stage 110 to a vertical projection area of the second heating region HR2B on the rotating stage 110. That is, the distribution density of the heaters located in the first heating region HR1 is not equal to the distribution density of the heaters located in the second heating region HR2B. In this way, the heater 130B can heat a plurality of regions of the wafer carrier 120, thereby improving the temperature uniformity of the epitaxial substrate ES.

In addition, the first heater 131a, the first heater 131b, and the first heater 131c may each have a first temperature, the second heater 132a and the second heater 132b may each have a second temperature, and the first temperature is not equal to the second temperature, helping improve the temperature uniformity of the epitaxial substrate ES, and enabling the epitaxial film TF developed on the epitaxial substrate ES to have favorable thickness uniformity.

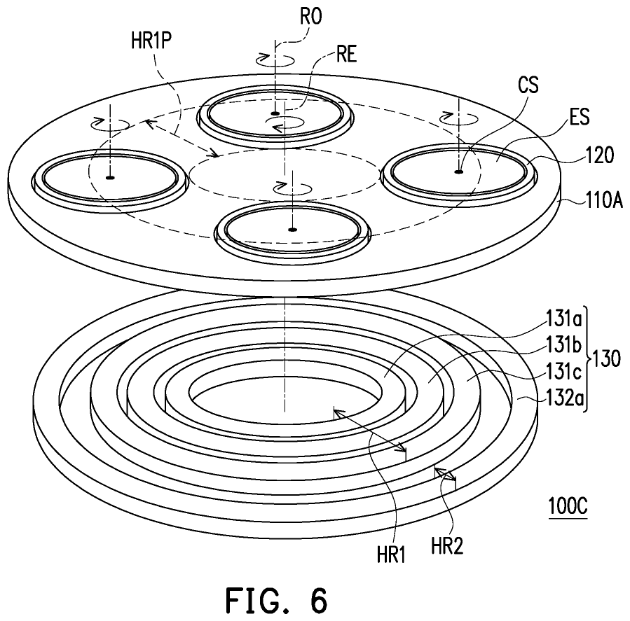

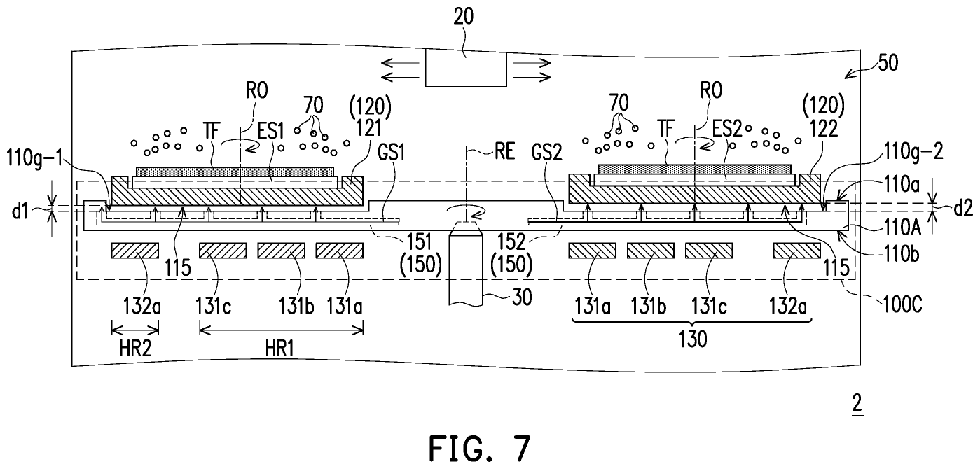

FIG. 6 is a schematic cross-sectional view of a heating apparatus according to a fourth embodiment of the invention. FIG. 7 is a schematic cross-sectional view of a CVD system according to another embodiment of the invention. It is specially noted that, for clear presentation, a wafer carrier driving unit 150 of FIG. 7 is omitted in FIG. 6.

Referring to FIG. 6 and FIG. 7, a main difference between a CVD system 2 and a heating apparatus 100C in the present embodiment and the CVD system 1 and the heating apparatus 100 in FIG. 2 is that the heating apparatus 100C further includes the wafer carrier driving unit 150, configured to drive the wafer carrier 120 to spin on a spinning axis RO, where the spinning axis RO passes through the symmetry center CS of the wafer carrier 120. In the present embodiment, the wafer carrier driving unit 150 includes a plurality of gas pipelines disposed in a rotating stage 110A, for example, a gas pipeline 151 and a gas pipeline 152, and the gas pipelines are located below the wafer carrier 120. These gas pipelines are configured to deliver an airflow to grooves (for example, a groove 110g-1 and a groove 110g-2) of the rotating stage 110A to flow between the wafer carrier 120 and the rotating stage 110A, so that a spacing 115 is formed between the wafer carrier 120 disposed in the grooves and the first surface 110a of the rotating stage 110A in the axial direction of the rotating axis RE, and the airflow drives the wafer carrier 120 to rotate. In this way, the temperature uniformity in the epitaxial substrate ES can be further improved. It should be noted that, in the present embodiment, a rotation direction and a spinning direction of the wafer carrier 120 are optionally the same (for example, are a clockwise direction), but the invention is not limited thereto. In other embodiments, alternatively, the rotation direction and the spinning direction of the wafer carrier 120 may be respectively a clockwise direction and a counterclockwise direction.

In the present embodiment, the wafer carrier driving unit 150 delivers a first airflow GS1 to the groove 110g-1 in which the wafer carrier 121 is disposed, so that there is a first distance d1 between the wafer carrier 121 and the rotating stage 110A in the axial direction of the rotating axis RE. The wafer carrier driving unit 150 delivers a second airflow GS2 to the groove 110g-2 in which the wafer carrier 122 is disposed, so that there is a second distance d2 between the wafer carrier 122 and the rotating stage 110A in the axial direction of the rotating axis RE. Relative amounts of the first airflow GS1 and the second airflow GS2 are adjusted, so that the first distance d1 between the wafer carrier 121 and the rotating stage 110A is not equal to the second distance d2 between the wafer carrier 122 and the rotating stage 110A. For example, when there is a temperature difference between an epitaxial substrate ES1 and an epitaxial substrate ES2, a unit time flow of the first airflow GS1 is set to be less than a unit time flow of the second airflow GS2, to make the first distance d1 less than the second distance d2, to further reduce the temperature difference between the two epitaxial substrates. Alternatively, spinning speeds of these wafer carriers may be adjusted by using different airflows to improve film uniformity and improve epitaxial quality.

Based on the above, in the heating apparatus and the CVD system in an embodiment of the invention, the first spacing between the two adjacent first heaters located in the first heating region is not equal to the spacing between the first heating region and the second heating region, so that the temperature uniformity of the epitaxial substrate can be effectively improved, the film developed on the epitaxial substrate may have favorable thickness uniformity, and uniformity of light emission of a subsequently formed micro light-emitting diode chip is also improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heating apparatus, comprising:
a rotating stage, comprising a rotating axis;
a plurality of wafer carriers, disposed on the rotating stage, wherein the rotating stage drives the wafer carriers to rotate on the rotating axis;
a plurality of first heaters, disposed under a first heating region of the rotating stage, wherein there is a first spacing between any two adjacent first heaters, and each of the first heaters comprises a first width in a radial direction of the rotating stage; and
at least one second heater, disposed under a second heating region of the rotating stage, wherein the second heater comprises a second width in the radial direction of the rotating stage, there is a spacing between the second heating region and the first heating region, the spacing is not equal to the first spacing, and the first width is equal to the second width.

2. The heating apparatus according to claim 1, wherein the spacing between the second heating region and the first heating region is the smallest spacing between the second heater and one of the first heaters.

3. The heating apparatus according to claim 1, wherein the first heating region comprises a radial width in the radial direction of the rotating stage, the wafer carrier comprises a wafer carrier diameter, and a ratio of the radial width to the wafer carrier diameter is greater than 0.5 and less than 1.

4. The heating apparatus according to claim 1, wherein the second heating region comprises a plurality of second heaters, there is a second spacing between any two adjacent second heaters, and the second spacing is not equal to the first spacing.

5. The heating apparatus according to claim 4, wherein a ratio of a vertical projection area of the first heaters on the rotating stage to a vertical projection area of the first heating region on the rotating stage is not equal to a ratio of a vertical projection area of the second heaters on the rotating stage to a vertical projection area of the second heating region on the rotating stage.

6. The heating apparatus according to claim 1, wherein the first heaters comprise a first temperature, the second heater comprises a second temperature, and the first temperature is not equal to the second temperature.

7. The heating apparatus according to claim 1, wherein a vertical projection of each of the wafer carriers on the rotating stage partially overlaps a vertical projection of the first heating region on the rotating stage, and a ratio of a vertical projection area of the first heating region on the wafer carrier to an area of the wafer carrier is greater than or equal to 0.4 and less than or equal to 0.9.

8. The heating apparatus according to claim 1, wherein the wafer carriers comprise a symmetry center each, and the symmetry centers overlap a vertical projection of the first heating region on the wafer carriers.

9. A chemical vapor deposition system, comprising:
a chamber;
a heating apparatus, disposed in the chamber, wherein the heating apparatus comprises:
a rotating stage, comprising a rotating axis;
a plurality of wafer carriers, disposed on the rotating stage, wherein the rotating stage drives the wafer carriers to rotate on the rotating axis;
a plurality of first heaters, disposed under a first heating region of the rotating stage, wherein there is a first spacing between any two adjacent first heaters, and each of the first heaters comprises a first width in a radial direction of the rotating stage; and
at least one second heater, disposed under a second heating region of the rotating stage, wherein the second heater comprises a second width in the radial direction of the rotating stage, there is a spacing between the second heating region and the first heating region, the spacing is not equal to the first spacing, and the first width is equal to the second width;
a rotation driving mechanism, connected to the rotating stage and driving the rotating stage to rotate; and
an air inlet unit, disposed in the chamber and located above the rotating stage.

10. The chemical vapor deposition system according to claim 9, wherein the spacing between the second heating region and the first heating region is the smallest spacing between the second heater and one of the first heaters.

11. The chemical vapor deposition system according to claim 9, wherein the first heating region comprises a radial width in the radial direction of the rotating stage, the wafer carrier comprises a wafer carrier diameter, and a ratio of the radial width to the wafer carrier diameter is greater than 0.5 and less than 1.

12. The chemical vapor deposition system according to claim 9, wherein the second heating region comprises a plurality of second heaters, there is a second spacing between any two adjacent second heaters, and the second spacing is not equal to the first spacing.

13. The chemical vapor deposition system according to claim 12, wherein a ratio of a vertical projection area of the first heaters on the rotating stage to a vertical projection area of the first heating region on the rotating stage is not equal to a ratio of a vertical projection area of the second heaters on the rotating stage to a vertical projection area of the second heating region on the rotating stage.

14. The chemical vapor deposition system according to claim 9, wherein the first heaters comprise a first temperature, the second heater comprises a second temperature, and the first temperature is not equal to the second temperature.

15. The chemical vapor deposition system according to claim 9, wherein a vertical projection of each of the wafer carriers on the rotating stage partially overlaps a vertical projection of the first heating region on the rotating stage, and a ratio of a vertical projection area of the first heating region on the wafer carrier to an area of the wafer carrier is greater than or equal to 0.4 and less than or equal to 0.9.

16. The chemical vapor deposition system according to claim 9, wherein the wafer carriers comprise a symmetry center each, and the symmetry centers overlap a vertical projection of the first heating region on the wafer carriers.

17. The chemical vapor deposition system according to claim 9, wherein the heating apparatus further comprises:
a wafer carrier driving unit, disposed on the rotating stage, and configured to drive each of the wafer carriers to respectively spin on its spinning axis.

18. The chemical vapor deposition system according to claim 17, wherein the wafer carrier driving unit comprises a plurality of gas pipelines disposed in the rotating stage, and the gas pipelines are located under the wafer carriers.

19. The chemical vapor deposition system according to claim 17, wherein there is a spacing between each of the wafer carriers and the rotating stage in an axial direction of the rotating axis.

20. The chemical vapor deposition system according to claim 17, wherein there is a first distance between a first wafer carrier of the wafer carriers and the rotating stage in an axial direction of the rotating axis, there is a second distance between a second wafer carrier of the wafer carriers and the rotating stage in the axial direction of the rotating axis, and the first distance is not equal to the second distance.
